(19) United States
(12) Patent Application Publication
(10) Pub. No.: US 2026/0190363 A1
(43) Pub. Date: Jul. 2, 2026

(54) HETEROJUNCTION BIPOLAR TRANSISTOR DEVICE

(71) Applicant: QUANZHOU SANAN INTEGRATED CIRCUIT CO., LTD., Quanzhou City (CN)

(72) Inventors: Keun-Yong BAN, Quanzhou City (CN); Fuchin CHANG, Xiamen City (CN); Minzhen ZHONG, Quanzhou City (CN)

(21) Appl. No.: 19/423,403

(22) Filed: Dec. 17, 2025

(30) Foreign Application Priority Data
Dec. 31, 2024 (CN) 202411997232.9

(51) Int. Cl. H10D 10/80; H10D 10/01; H10D 62/13; H10D 62/17; H10D 62/852

(52) U.S. Cl. CPC H10D 10/821; H10D 10/021; H10D 62/136; H10D 62/138; H10D 62/177; H10D 62/852

(57) ABSTRACT

A heterojunction bipolar transistor device includes a collector region, a base region, and an emitter region. The collector region has a composition of GaAs. The base region is disposed on the collector region. The emitter region is disposed on the base region and has a composition of InGaP. The base region includes a gradient layer that has a composition of In₍ₓ₎Ga₍₁₋ₓ₎As_{(1-y)}Sb_{(y)}, where each of a value of x and a value of y gradually increases or decreases between a base-collector interface of the base region and the collector region and a base-emitter interface of the base region and the emitter region. An increasing or decreasing direction of the value of x and an increasing or decreasing direction the value of y are opposite to each other.

### CROSS-REFERENCE TO RELATED APPLICATION

This application claims priority to Chinese Invention Patent Application No. CN202411997232.9, filed on Dec. 31, 2024, the entire disclosure of which is incorporated by reference herein.

### FIELD

The disclosure relates to a semiconductor device, and more particularly to a heterojunction bipolar transistor device.

### BACKGROUND

In recent years, high-performance heterojunction bipolar transistors (HBTs) have attracted much attention for power amplifier (PA) applications in microwave circuits. In order to meet the demand for low-power operation, the requirement to achieve a high additional power efficiency (PAE) at low bias voltage has surfaced. To fulfill such requirement, base-emitter voltage (V_{be}) and offset voltage (V_{offset}) need to be significantly reduced. The base-emitter voltage in a heterojunction bipolar transistor is closely related to bandgap energy (E_{g}) of a base region material.

For base region materials, III-V compound semiconductors including indium gallium arsenide (InGaAs) and gallium arsenide antimony (GaAsSb) are often used. The bandgap energy may be reduced by adding indium (In) and antimony (Sb), but such method may lead to a lattice mismatch, which produces crystalline defects due to the increased compressive strain caused by an increase in a lattice constant. Therefore, the composition of indium and antimony needs to be controlled so as to minimize the defects within a critical thickness of a base region, thereby maintaining the performance of the heterojunction bipolar transistor. However, this results in mitigating the bandgap energy drop and, in turn, the base-emitter voltage reduction. On the other hand, obtaining the high current gain is one of the most fundamental parts in terms of the device performance. The proper epitaxial layer design of the compositional gradient in the base region may increase the current gain. These limiting factors make designing an epitaxial layer and a device of the heterojunction bipolar transistor difficult, thereby limiting applications thereof.

### SUMMARY

Therefore, an object of the disclosure is to provide an heterojunction bipolar transistor device that can alleviate at least one of the drawbacks of the prior art.

According to the disclosure, the heterojunction bipolar transistor device includes a collector region, a base region, and an emitter region.

The collector region has a composition of GaAs. The base region is disposed on the collector region. The emitter region is disposed on the base region and has a composition of InGaP. The base region includes a gradient layer that has a composition of In₍ₓ₎Ga₍₁₋ₓ₎As_{(1-y)}Sb_{(y)}, where each of a value of x and a value of y gradually increases or decreases between a base-collector interface of the base region and the collector region and a base-emitter interface of the base region and the emitter region. An increasing or decreasing direction of the value of x and an increasing or decreasing direction the value of y are opposite to each other.

### BRIEF DESCRIPTION OF THE DRAWINGS

Other features and advantages of the disclosure will become apparent in the following detailed description of the embodiment(s) with reference to the accompanying drawings. It is noted that various features may not be drawn to scale.

FIG. 1 is a schematic view illustrating a first embodiment of a heterojunction bipolar transistor device according to the disclosure.

FIG. 2 is a schematic view illustrating varying energy band structure of a collector region, a base region, and an emitter region of the first embodiment.

FIG. 3 is a graph illustrating changes in bandgaps of the collector region, the base region, and the emitter region of the first embodiment.

FIG. 4 is a Gummel plot illustrating a relationship between base and collector electric currents (Ic and Ib) and a base-emitter voltage (Vbe) of the first embodiment.

FIG. 5 is a schematic view illustrating a second embodiment of the heterojunction bipolar transistor device according to the disclosure.

FIG. 6 is a schematic view illustrating varying energy band structure of the collector region, the base region having a gradient layer, and the emitter region of the second embodiment.

FIG. 7 is a schematic view illustrating a third embodiment of the heterojunction bipolar transistor device according to the disclosure.

FIG. 8 is a schematic view illustrating a fourth embodiment of the heterojunction bipolar transistor device according to the disclosure.

### DETAILED DESCRIPTION

Before the disclosure is described in greater detail, it should be noted that where considered appropriate, reference numerals or terminal portions of reference numerals have been repeated among the figures to indicate corresponding or analogous elements, which may optionally have similar characteristics.

It should be noted herein that for clarity of description, spatially relative terms such as “top,” “bottom,” “upper,” “lower,” “on,” “above,” “over,” “downwardly,” “upwardly” and the like may be used throughout the disclosure while making reference to the features as illustrated in the drawings. The features may be oriented differently (e.g., rotated 90 degrees or at other orientations) and the spatially relative terms used herein may be interpreted accordingly.

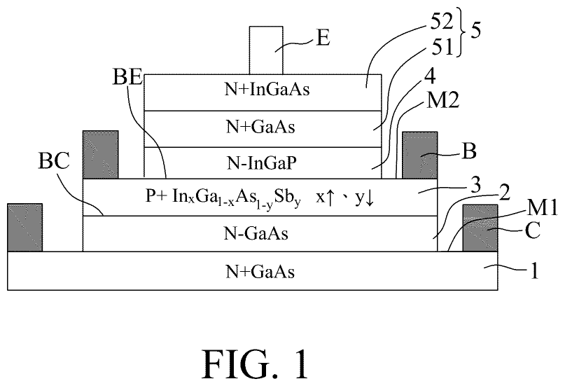

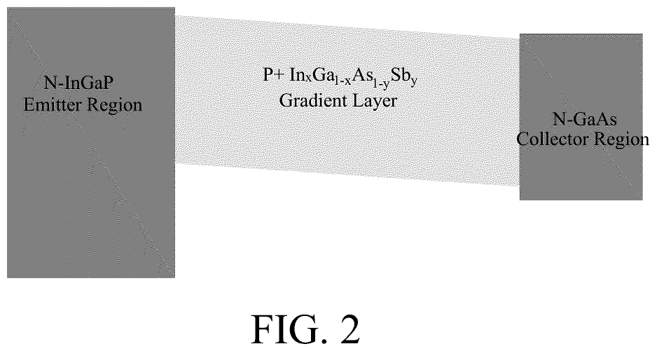

Referring to FIG. 1, a first embodiment of an heterojunction bipolar transistor includes a collector region 2 that has a composition of N−GaAs, a base region 3 that is disposed on the collector region 2 and that includes a gradient layer having a composition of P+In₍ₓ₎Ga₍₁₋ₓ₎As_{(1-y)}Sb_{(y)}, and an emitter region 4 that is disposed on the base region 3 and that has a composition of N−InGaP. The collector region 2 has a donor doping concentration ranging from 1×10¹⁵/cm³ to 1×10¹⁸/cm³. The collector region 2 may have a multilayered structure and a thickness ranging from 0.5 μm to 2.5 μm. The base region 3 has a thickness ranging from 20 nm to 100 nm and an acceptor doping concentration ranging from 2×10¹⁹/cm³ to 6×10¹⁹/cm³. The emitter region 4 has a composition of N−In_{0.51}Ga_{0.49}P, a donor doping concentration ranging from 1×10¹⁷/cm³ to 6×10¹⁷/cm³, and a thickness ranging from 10 nm to 100 nm. An interface of the base region 3 and the collector region 2 is defined as a base-collector interface (BC), and an interface of the base region 3 and the emitter region 4 is defined as a base-emitter interface (BE). In this embodiment, in the gradient layer, a value of x gradually increases and a value of y gradually decreases in a direction from the base-collector interface (BC) to the base-emitter interface (BE). FIG. 2 illustrates varying energy band structure of the collector region 2, the base region 3, and the emitter region 4, and 0.001≤x≤0.15 and 0.001≤y≤0.15. An Sb content increase in the InGaAsSb material causes the bandgap energy to decrease in the valence band mostly whereas the bandgap energy decreases in the conduction band mostly when an In content increases in the InGaAsSb material. Thus, the current gain increases while a low base-emitter voltage (V_{be}) is maintained when the In increases and Sb decreases simultaneously in this composition window. The base region 3 that has a compositional grading that forms an electric potential gradient across the entire base region 3, which reduces the base transfer time (τB) and thus improves the current gain. In addition, an increasing or decreasing direction of the In content being opposite to those of the Sb content enables better lattice matching of an effective lattice constant with adjacent layers, reduces defects caused by compressive strains, improves the quality of crystal growth, and thus achieves better performance.

A sub-collector region 1 having a composition of N+GaAs is disposed on the collector region 2, and has a donor doping concentration greater than that of the collector region 2. For example, the sub-collector region 1 has a thickness ranging from approximately 0.5 μm to 1.5 μm and the donor doping concentration ranging from 3×10¹⁸/cm³ to 5×10¹⁸/cm³. In other embodiments, other functional layers may be disposed between the collector region 2 and the sub-collector region 1, and is not limited thereto. A heavily doped N-type contact layer 5 is also disposed on the emitter region 4 to improve contact performance with electrodes. For example, the N-type contact layer 5 may sequentially include a first contact portion 51 having a composition of N+GaAs and a second contact portion 52 having a composition of N+In_{z}Ga_{(1-z)}As that is disposed on the first contact portion 51. The first contact portion 51 has a donor doping concentration ranging from 2×10¹⁸/cm3 to 6×10¹⁸/cm³ and a thickness ranging from approximately 50 nm to 200 nm. The second contact portion 52 has an In content (z) that gradually changes from 0.5 to 0.6, a donor doping concentration greater than 1×10¹⁹/cm³, and a thickness ranging from approximately 50 nm to 300 nm. An emitter electrode (E) is disposed on the second contact portion 52. The base region 3 has a second mesa surface (M2) and a base electrode (B) that is disposed on the second mesa surface (M2). The sub-collector region 1 has a first mesa surface (M1) and a collector electrode (C) that is disposed on the first mesa surface (M1).

In a method for manufacturing the first embodiment of the heterojunction bipolar transistor device, an epitaxial structure of the heterojunction bipolar transistor device is a stacked structure grown on a substrate using metal organic chemical vapor deposition (MOCVD) or molecular beam epitaxy (MBE). The substrate may be a GaAs substrate, and an N+GaAs sub-collector region 1, an N−GaAs collector region 2, a P+In₍ₓ₎Ga₍₁₋ₓ₎As_{(1-y)}Sb_{(y)}base region 3, an N−InGaP emitter region 4, an N+GaAs first contact portion 51, and an N+In_{z}Ga_{(1-z)}As second contact portion 52 are sequentially formed in such order on the GaAs substrate. An etching process is performed to expose a portion of the P+In₍ₓ₎Ga₍₁₋ₓ₎As_{(1-y)}Sb_{(y)}base region 3 to form the second mesa surface (M2), and to expose a portion of the N+GaAs sub-collector region 1 to form the first mesa surface (M1). The emitter electrode (E) is disposed on the N+In_{z}Ga_{(1-z)}As second contact portion 52, the base electrode (B) is disposed on the second mesa surface (M2), and the collector electrode (C) is disposed on the first mesa surface (M1) using metal craft processes so as to form a complete device structure. For example, the N-InGaP emitter region 4 is doped with Si. When growing the P+In₍ₓ₎Ga₍₁₋ₓ₎As_{(1-y)}Sb_{(y)}base region 3, the p-type doping element may be C or Be. The content of each component may be modulated by conventional methods, such as by varying the input parameters of the growth source. For example, when using an MBE process, conventional methods, such as linearly varying the temperature of each growth source, may achieve a linear modulation of flow rates of precursors, thereby achieving the aforementioned gradient change.

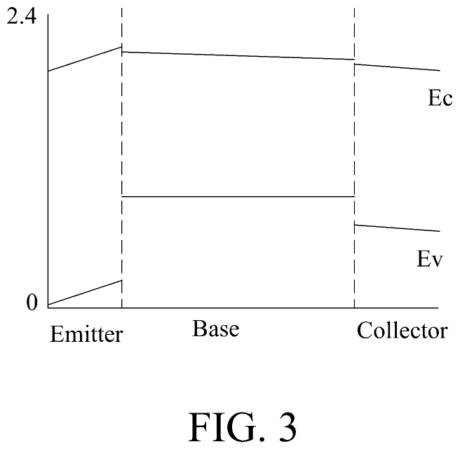

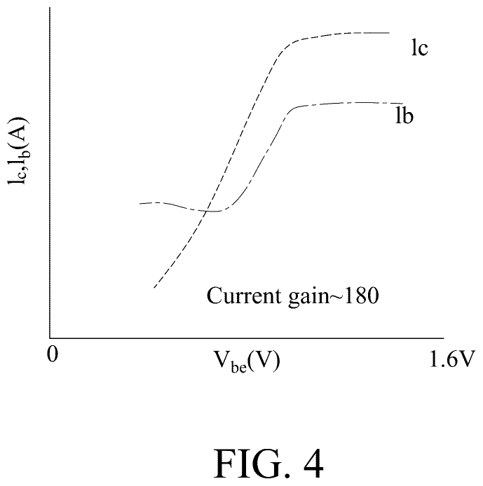

Specifically, in some embodiments, an In content (x) of the P+In₍ₓ₎Ga₍₁₋ₓ₎As_{(1-y)}Sb_{(y)}base region 3 gradually increases from 0.06 to 0.1, and an Sb content (y) of the P+In₍ₓ₎Ga₍₁₋ₓ₎As_{(1-y)}Sb_{(y)}base region 3 decreases from 0.04 to 0.001 in the direction from the base-collector interface (BC) to the base-emitter interface (BE). The energy band structure of the emitter region 4, the base region 3, and the collector region 2 is shown in FIG. 3. Based on the energy band structure shown in FIG. 2, a Gummel plot of a DC device was obtained through simulation. FIG. 4 illustrates that such configuration achieves a current gain of 180.

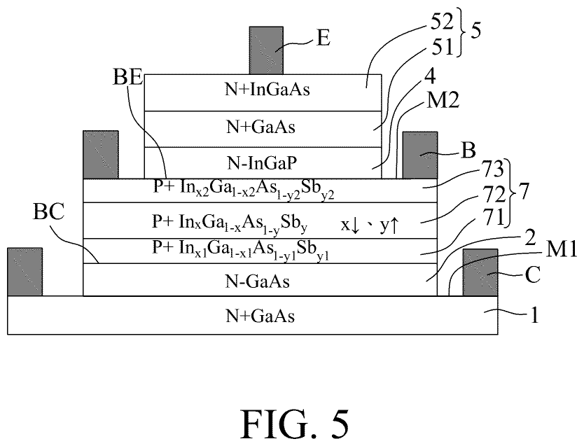

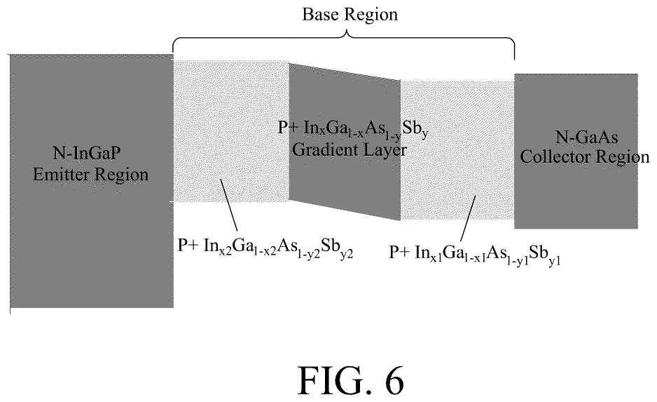

Referring to FIG. 5, a second embodiment of the heterojunction bipolar transistor device includes the collector region 2 that has a composition of N−GaAs, a base region 7 that is disposed on the collector region 2 and that includes a gradient layer 72 having a composition of P+In₍ₓ₎Ga₍₁₋ₓ₎As_{(1-y)}Sb_{(y)}, and the emitter region 4 that is disposed on the base region 7 and that has a composition of N−InGaP. The collector region 2 has a donor doping concentration ranging from 1×10¹⁵/cm³ to 1×10¹⁸/cm³. The collector region 2 may have a multilayered structure and a thickness ranging from 0.5 μm to 2.5 μm. The emitter region 4 has a composition of N−In_{0.51}Ga_{0.49}P, a donor doping concentration ranging from 1×10¹⁷/cm³ to 6×10¹⁷/cm³, and a thickness ranging from 10 nm to 100 nm. An interface of the base region 7 and the collector region 2 is defined as a base-collector interface (BC), and an interface of the base region 7 and the emitter region 4 is defined as a base-emitter interface (BE). In the direction from the base-collector interface (BC) to the base-emitter interface (BE), the base region 7 sequentially includes a first stable portion 71 that is disposed on one side of the gradient layer 72 and that has composition of P+In₍ₓ₁₎Ga₍₁₋ₓ₁₎As_{(1-y1)}Sb_{(y1)}, the gradient layer 72, and a second stable portion 73 that is disposed on another side of the gradient layer 72 and that has a composition of P+In₍ₓ₂₎Ga₍₁₋ₓ₂₎As_{(1-y2)}Sb_{(y2}). In this embodiment, 0.001≤x1≤0.15, 0.001≤y1≤0.15, 0.001≤x≤0.15, 0.001≤y≤0.15, 0.001≤x2≤0.15, and 0.001≤y2≤0.15. A thickness of the first stable portion 71 ranges from 1 nm to 30 nm, a thickness of the gradient layer 72 ranges from 10 nm to 100 nm, and a thickness of the second stable portion 73 ranges from 1 nm to 30 nm. Each of the first stable portion 71, the gradient layer 72, and the second stable portion 73 has an acceptor doping concentrations ranging from 2×10¹⁹/cm³ to 6×10¹⁹/cm³. In the gradient layer 72, an increasing or decreasing direction of an In content (x) and an increasing or decreasing direction of an Sb content (y) are opposite to each other. A value of each of x1, x2, y1, and y2 is a constant value. In the gradient layer 72, a value of x ranges from the value of x1 to the value of x2, and a value of y ranges from the value of y1 to the value of y2. More specifically, in a direction toward the base-emitter interface (BE) or the emitter region 4, the value of x gradually changes to become the value of x2, and the value of y gradually changes to become the value of y2. In other words, in a side of the gradient layer 72 that is proximate to the second stable portion 73, the value of x equals the value of x2 and the value of y equals the value of y2. In this embodiment, in the direction from the base-collector interface (BC) to the base-emitter interface (BE) or toward the emitter region 4, the In content (x) gradually decreases, and the Sb content (y) gradually increases, so that x1>x2, y1<y2, as shown in the varying energy band structure of FIG. 6, which forms a structure having a partially gradient energy band.

In this embodiment, a similar technical effect is achieved by having a base region that has at least one stable layer and a gradient layer. Compared to the critical thickness limitations of GaAsSb materials, InGaAsSb materials offer greater control over gradient of components and electric potential gradient, and improves current gain while simultaneously reducing base-emitter voltage (V_{be}), thereby resulting in better performance overall.

The sub-collector region 1 having a composition of N+GaAs is disposed on the collector region 2, and has a doping concentration greater than that of the collector region 2. For example, the sub-collector region 1 has a thickness ranging from approximately 0.5 μm to 1.5 μm, and the donor doping concentration ranging from 3×10¹⁸/cm³ to 5×10¹⁸/cm³. In other embodiments, other functional layers may be disposed between the collector region 2 and the sub-collector region 1, and is not limited thereto. A heavily doped N-type contact layer 5 is also disposed on the emitter region 4 to improve the contact performance with the electrodes. For example, the N-type contact layer 5 may sequentially include the first contact portion 51 having a composition of N+GaAs and the second contact portion 52 having a composition of N+InzGa_{(1-z)}As that is disposed on the first contact portion 51. The first contact portion 51 has a donor doping concentration of 2×10¹⁸/cm3 to 6×10¹⁸/cm³ and a thickness ranging from approximately 50 nm to 200 nm. The second contact portion 52 has an In content (z) smaller than 1 (z<1 ) and ranging from 0.5 to 0.6, a donor doping concentration greater than 1×10¹⁹/cm³, and a thickness ranging from approximately 50 nm to 300 nm. The emitter electrode (E) is disposed on the second contact portion 52. The base region 7 has the second mesa surface (M2) and the base electrode (B) that is disposed on the second mesa surface (M2). The sub-collector region 1 has the first mesa surface (M1) and the collector electrode (C) that is disposed on the first mesa surface (M1).

In a method for manufacturing the second embodiment of the heterojunction bipolar transistor device, the epitaxial structure of the heterojunction bipolar transistor device is a stacked structure grown on the substrate using metal organic chemical vapor deposition (MOCVD) or molecular beam epitaxy (MBE). The substrate may be a GaAs substrate, and the N+GaAs sub-collector region 1, the N−GaAs collector region 2, a P+In₍ₓ₎Ga₍₁₋ₓ₎As_{(1-y)}Sb_{(y)}base region 7, the N−InGaP emitter region 4, the N+GaAs first contact portion 51, and the N+In_{z}Ga_{(1-z)}As second contact portion 52 are sequentially formed in such order on the GaAs substrate. The etching process is performed to expose a portion of the P+In₍ₓ₂₎Ga₍₁₋ₓ₂₎As_{(1-y2)}Sb_{(y2)}second stable portion 73 to form the second mesa surface (M2), to expose the portion of the N+GaAs sub-collector region 1 to form the first mesa surface (M1). The emitter electrode (E) is disposed on the N+In_{z}Ga_{(1-z)}As second contact portion 52, the base electrode (B) is disposed on the second mesa surface (M2), and the collector electrode (C) is disposed on the first mesa surface (M1) using metal craft processes so as to form a complete device structure. For example, the N−InGaP emitter region 4 is doped with Si. When growing the P+In₍ₓ₎Ga₍₁₋ₓ₎As_{(1-y)}Sb_{(y)}base region 7, the p-type doping element may be C or Be. The content of each component may be modulated by conventional methods, such as by varying the input parameters of the growth source. For example, using the MBE process, the P+In₍ₓ₁₎Ga₍₁₋ₓ₁₎As_{(1-y1)}Sb_{(y1)}first stable portion 71 having a constant composition is grown using constant growth parameters. The P+In₍ₓ₎Ga₍₁₋ₓ₎As_{(1-y)}Sb_{(y)}gradient layer 72 is then grown by linearly varying the temperature of each growth source. Finally, the P+In₍ₓ₂₎Ga₍₁₋ₓ₂₎As_{(1-y2)}Sb_{(y2)}second stable portion 73 having a constant composition is grown using constant growth parameters.

In some embodiments, in the direction from the base-collector interface (BC) to the base-emitter interface (BE), the base region 7 sequentially includes the P+In_{0.050}Ga_{0.950}As_{0.999}Sb_{0.001} first stable portion 71 that is disposed on one side of the P+In₍ₓ₎Ga₍₁₋ₓ₎As_{(1-y)}Sb_{(y)}gradient layer 72, the P+In₍ₓ₎Ga₍₁₋ₓ₎As_{(1-y)}Sb_{(y)} gradient layer 72, and the P+In_{0.001}Ga_{0.999}As_{0.9}Sb_{0.1} second stable portion 73 that is disposed on another side of the P+In₍ₓ₎Ga₍₁₋ₓ₎As_{(1-y)}Sb_{(y)}gradient layer 72. In the P+In₍ₓ₎Ga₍₁₋ₓ₎As_{(1-y)}Sb_{(y)}gradient layer 72, the value of x gradually decreases from 0.05 to 0.001, and the value of y gradually increases from 0.001 to 0.1.

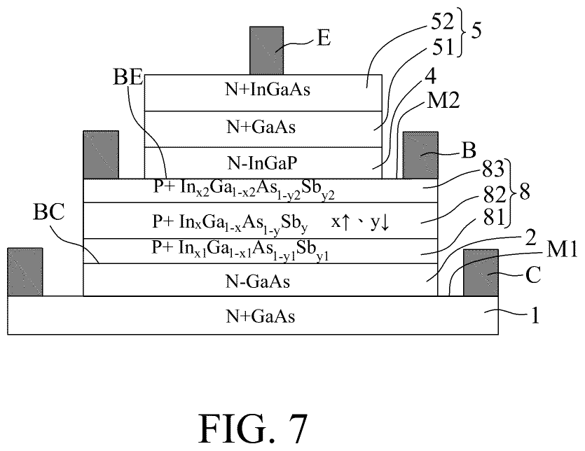

Referring to FIG. 7, a third embodiment of the heterojunction bipolar transistor device includes the collector region 2 that has a composition of N−GaAs, a base region 8 that is disposed on the collector region 2 and that includes a gradient layer 82 having a composition of P+In₍ₓ₎Ga₍₁₋ₓ₎As_{(1-y)}Sb_{(y)}, and the emitter region 4 that is disposed on the base region 8 and that has a composition of N−InGaP. The collector region 2 has a donor doping concentration ranging from 1×10¹⁵/cm³ to 1×10¹⁸/cm³. The collector region 2 may have a multilayered structure and a thickness ranging from 0.5 μm to 2.5 μm. The gradient layer 82 has a thickness ranging from 20 nm to 100 nm and an acceptor doping concentration ranging from 2×10¹⁹/cm³ to 6×10¹⁹/cm³. The emitter region 4 has a composition of N−In_{0.51}Ga_{0.49}P, a donor doping concentration ranging from 1×10¹⁷/cm³ to 6×10¹⁷/cm³, and a thickness ranging from 10 nm to 100 nm. An interface of the base region 8 and the collector region 2 is defined as a base-collector interface (BC), and an interface of the base region 8 and the emitter region 4 is defined as the base-emitter interface (BE). In the direction from the base-collector interface (BC) to the base-emitter interface (BE), the base region 8 sequentially includes a first stable portion 81 that is disposed on one side of the gradient layer 82 and that has a composition of P+In₍ₓ₁₎Ga₍₁₋ₓ₁₎As_{(1-y1)}Sb_{(y1)}, the gradient layer 82, and a second stable portion 83 that is disposed on another side of the gradient layer 82 and that has a composition of P+In₍ₓ₂₎Ga₍₁₋ₓ₂₎As_{(1-y2)}Sb_{(y2)}, where 0.001≤x1≤0.15, 0.001≤y1≤0.15, 0.001≤x≤0.15, 0.001≤y≤0.15, 0.001≤x2≤0.15, and 0.001≤y2≤0.15. A thickness of the first stable portion 81 ranges from 1 nm to 30 nm, a thickness of the gradient layer 82 ranges from 10 nm to 100 nm, and a thickness of the second stable portion 83 ranges from 1 nm to 30 nm. An acceptor doping concentrations of each of the first stable portion 81, the gradient layer 82, and the second stable portion 82 ranges from 2×10¹⁹/cm³ to 6×10¹⁹/cm³. In the gradient layer 82, an increasing or decreasing direction of an In content (x) and an increasing or decreasing direction of an Sb content (y) are opposite to each other. A value of each of x1, x2, y1, and y2 is a constant value. In the gradient layer 82, a value of x ranges from the value of x1 to the value of x2, and a value of y ranges from the value of y1 to the value of y2. More specifically, in the direction toward the base-emitter interface (BE) or the emitter region 4, the value of x gradually changes to become the value of x2, and the value of y gradually changes to become the value of y2. In other words, in a side of the gradient layer 82 that is proximate to the second stable portion 83, the value of x equals the value of x2 and the value of y equals the value of y2. In this embodiment, in the direction from the base-collector interface (BC) to the base-emitter interface (BE) or toward the emitter region 4, the In content (x) gradually increases, and the Sb content (y) gradually decreases, so that x1<x2, y1>y2, which forms a structure having a partially gradient energy band.

A method for manufacturing the third embodiment of the heterojunction bipolar transistor device is substantially the same as that for manufacturing the second embodiment, and a similar effect may be achieved.

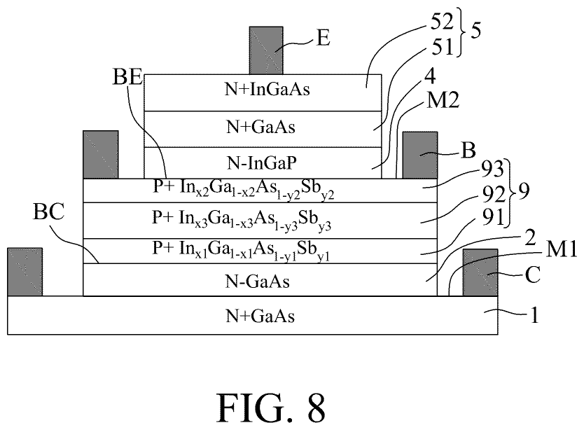

Referring to FIG. 8, a fourth embodiment of the heterojunction bipolar transistor device includes the collector region 2 that has a composition of N−GaAs, a base region 9 that is disposed on the collector region 2 and that includes a gradient layer 92 having a composition of P+In₍ₓ₃₎Ga₍₁₋ₓ₃₎As₍₁₋y3)Sb(y3), and the emitter region 4 that is disposed on the base region 9 and that has a composition of N−InGaP. An interface of the base region 9 and the collector region 2 is defined as a base-collector interface (BC), and an interface of the base region 9 and the emitter region 4 is defined as the base-emitter interface (BE). In the direction from the base-collector interface (BC) to the base-emitter interface (BE), the base region 9 sequentially includes a first stable portion 91 that is disposed on one side of the gradient layer 92 and that has a composition of P+In₍ₓ₁₎Ga₍₁₋ₓ₁₎As_{(1-y1)}Sb_{(y1)}, the gradient layer 92, and a second stable portion 93 that is disposed on another side of the gradient layer 92 and that has a composition of P+In₍ₓ₂₎Ga₍₁₋ₓ₂₎As_{(1-y2)}Sb_{(y2)}, where 0.001≤x1≤0.15, 0.001≤y1≤0.15, 0.001≤x3≤0.15, 0.001≤y3≤0.15, 0.001≤x2≤0.15, and 0.001≤y2≤0.15. The configuration of the gradient layer 92 is substantially the same as that of the gradient layer 72 having a composition of P+In₍ₓ₎Ga₍₁₋ₓ₎As_{(1-y)}Sb_{(y)}in the second embodiment or the gradient layer 82 having a composition of P+In₍ₓ₎Ga₍₁₋ₓ₎As_{(1-y)}Sb_{(y)}in the third embodiment. In the first stable portion 91, one of a value of x1 and a value of y1 is a constant value, and another one of the value of x1 and the value of y1 varies (a first condition). In the second stable portion 93, one of a value of x2 and a value of y2 is a constant value, and another one of the value of x2 and the value of y2 varies (a second condition). The first condition may or may not co-exist with the second condition. According to actual requirements, one or more components may vary for modulation. In a side of the gradient layer 92 that is proximate to the first stable portion 91, the value of x3 (In content) is similar or equal to the value of x1 and the value of y3 (Sb content) is similar or equal to the value of y1, so as to achieve composition continuity. In another side of the gradient layer 92 that is proximate to the second stable portion 93, the value of x3 (In content) is similar or equal to the value of x2 and the value of y3 (Sb content) is similar or equal to the value of y2, so as to achieve composition continuity. A method for manufacturing the fourth embodiment of the heterojunction bipolar transistor device is substantially the same as that for manufacturing the second embodiment, and a similar effect may be achieved.

In the description above, for the purposes of explanation, numerous specific details have been set forth in order to provide a thorough understanding of the embodiment(s). It will be apparent, however, to one skilled in the art, that one or more other embodiments may be practiced without some of these specific details. It should also be appreciated that reference throughout this specification to “one embodiment,” “an embodiment,” an embodiment with an indication of an ordinal number and so forth means that a particular feature, structure, or characteristic may be included in the practice of the disclosure. It should be further appreciated that in the description, various features are sometimes grouped together in a single embodiment, figure, or description thereof for the purpose of streamlining the disclosure and aiding in the understanding of various inventive aspects; such does not mean that every one of these features needs to be practiced with the presence of all the other features. In other words, in any described embodiment, when implementation of one or more features or specific details does not affect implementation of another one or more features or specific details, said one or more features may be singled out and practiced alone without said another one or more features or specific details. It should be further noted that one or more features or specific details from one embodiment may be practiced together with one or more features or specific details from another embodiment, where appropriate, in the practice of the disclosure.

While the disclosure has been described in connection with what is(are) considered the exemplary embodiment(s), it is understood that this disclosure is not limited to the disclosed embodiment(s) but is intended to cover various arrangements included within the spirit and scope of the broadest interpretation so as to encompass all such modifications and equivalent arrangements.

What is claimed is:

1. An heterojunction bipolar transistor device comprising:
a collector region having a composition of GaAs;
a base region disposed on said collector region; and
an emitter region disposed on said base region and having a composition of InGaP;
wherein said base region includes a gradient layer that has a composition of In₍ₓ₎Ga₍₁₋ₓ₎As_{(1-y)}Sb_{(y)}, where each of a value of x and a value of y gradually increases or decreases between a base-collector interface of said base region and said collector region and a base-emitter interface of said base region and said emitter region, an increasing or decreasing direction of said value of x and an increasing or decreasing direction said value of y being opposite to each other.

2. The heterojunction bipolar transistor device as claimed in claim 1, wherein 0.001≤x≤0.15 and 0.001≤y≤0.15.

3. The heterojunction bipolar transistor device as claimed in claim 1, wherein in said gradient layer, said value of x increases in a direction from said base-collector interface to said base-emitter interface, and said value of y decreases in the direction from said base-collector interface to said base-emitter interface.

4. The heterojunction bipolar transistor device as claimed in claim 3, wherein said base region has a thickness that ranges from 20 nm to 100 nm.

5. The heterojunction bipolar transistor device as claimed in claim 1, wherein said base region further includes at least one stable layer that has a composition of In₍ₓ₎Ga₍₁₋ₓ₎As_{(1-y)}Sb_{(y)}, where at least one of said value of x and said value of y is a constant value.

6. The heterojunction bipolar transistor device as claimed in claim 5, wherein:
said at least one stable layer includes a first stable portion that is disposed on one side of said gradient layer, and a second stable portion that is disposed on another side of said gradient layer opposite to said one side;
said first stable portion has a composition of In₍ₓ₁₎Ga₍₁₋ₓ₁₎As_{(1-y1)}Sb_{(y1)}, where at least one of a value of x1 and a value of y1 is a constant value, and said second stable portion has a composition of In₍ₓ₂₎Ga₍₁₋ₓ₂₎As_{(1-y2)}Sb_{(y2)}, where at least one of a value of x2 and a value of y2 is a constant value; and
in said gradient layer, said value of x ranges from said value of x1 to said value of x2, and said value of y ranges from said value of y1 to said value of y2.

7. The heterojunction bipolar transistor device as claimed in claim 6, wherein in said one side said gradient layer that is proximate to said first stable portion, said value of x equals said value of x1 and said value of y equals said value of y1, and in said another side of said gradient layer that is proximate to said second stable portion, said value of x equals said value of x2 and said value of y equals said value of y2.

8. The heterojunction bipolar transistor device as claimed in claim 6, wherein along a direction toward said emitter region, said value of x gradually decreases and said value of y gradually increases.

9. The heterojunction bipolar transistor device as claimed in claim 6, wherein along the direction toward said emitter region, said value of x gradually increases and said value of y gradually decreases.

10. The heterojunction bipolar transistor device as claimed in claim 6, wherein a thickness of said first stable portion ranges from 1 nm to 30 nm, a thickness of said gradient layer ranges from 10 nm to 100 nm, and a thickness of said second stable portion ranges from 1 nm to 30 nm.

11. The heterojunction bipolar transistor device as claimed in claim 1, wherein said collector region has a multilayered structure and a thickness that ranges from 0.5 μm to 2.5 μm.

12. The heterojunction bipolar transistor device as claimed in claim 1, wherein an acceptor doping concentration of said base region ranges from 2×10¹⁹/cm³ to 6×10¹⁹/cm³.

13. The heterojunction bipolar transistor device as claimed in claim 1, wherein a donor doping concentration of said emitter region ranges from 1×10¹⁷/cm³ to 6×10¹⁷/cm³.

14. The heterojunction bipolar transistor device as claimed in claim 1, wherein a thickness of said emitter region ranges from 10 nm to 100 nm.

15. The heterojunction bipolar transistor device as claimed in claim 1, further comprising a sub-collector region having a composition of GaAs and disposed on said collector region, a donor doping concentration of said sub-collector region being greater than a donor doping concentration of said collector region.

16. The heterojunction bipolar transistor device as claimed in claim 15, wherein said sub-collector region has a first mesa surface and at least one collector electrode that is disposed on said first mesa surface, and said base region has a second mesa surface and at least one base electrode that is disposed on said second mesa surface, said emitter region having at least one emitter electrode that is disposed thereon.

17. The heterojunction bipolar transistor device as claimed in claim 15, wherein said sub-collector region has a thickness that ranges from 0.5 μm to 1.5 μm and a donor doping concentration that ranges from 3×10¹⁸/cm³ to 5×10¹⁸/cm³.

18. The heterojunction bipolar transistor device as claimed in claim 15, further comprising at least one contact layer disposed on said emitter region, said emitter electrode being disposed on said at least one contact layer;
wherein said at least one contact layer includes a first contact portion and a second contact portion that is disposed on said first contact portion, and
said first contact portion has a composition of N+GaAs and said second contact portion has a composition of N+In_{z}Ga_{(1-z)}As, where a value of z gradually increases in a direction away from said first contact portion, z<1.

19. The heterojunction bipolar transistor device as claimed in claim 18, wherein said first contact portion has a donor doping concentration that ranges from 2×10¹⁸/cm3 to 6×10¹⁸/cm³ and a thickness that ranges from 50 nm to 200 nm.

20. The heterojunction bipolar transistor device as claimed in claim 18, wherein said second contact portion has a donor doping concentration that is greater than 1×10¹⁹/cm³ and a thickness that ranges from 50 nm to 300 nm.
